(19) United States
(12) Patent Application Publication
(10) Pub. No.: US 2025/0311493 A1
(43) Pub. Date: Oct. 2, 2025

(54) DEVICE FOR MANUFACTURING DISPLAY APPARATUS AND METHOD OF MANUFACTURING DISPLAY APPARATUS

(71) Applicant: Samsung Display Co., Ltd., Yongin-si (KR)

(72) Inventor: Sungmin Huch, Yongin-si (KR)

(73) Assignee: Samsung Display Co., Ltd., Yongin-si (KR)

(21) Appl. No.: 19/011,011

(22) Filed: Jan. 6, 2025

(30) Foreign Application Priority Data
Apr. 2, 2024 (KR) 10-2024-0044932

(51) Int. Cl. H10H 29/01

(52) U.S. Cl. CPC H10H 29/01

(57) ABSTRACT

A device for manufacturing a display apparatus may include a chamber, a susceptor disposed in the chamber, a diffuser facing the susceptor, a shadow frame disposed between the susceptor and the diffuser, a fixing member disposed on at least one of inner sides of the chamber, and a flow control member disposed on the at least one of the inner sides of the chamber to correspond to the fixing member and including at least a part disposed under the susceptor, wherein the flow control member is slidable in a direction upon being coupled to the fixing member.

### CROSS-REFERENCE TO RELATED APPLICATION(S)

This application claims priority under 35 U.S.C. § 119 to and benefits of Korean Patent Application No. 10-2024-0044932 filed on Apr. 2, 2024 in the Korean Intellectual Property Office, the entire contents of which are incorporated herein by reference.

### BACKGROUND

### 1. Technical Field

One or more embodiments relate to a device for manufacturing a display apparatus and a method of manufacturing a display apparatus, and a display apparatus may include a light-emitting diode.

### 2. Description of the Related Art

Display apparatuses visually display data. A display apparatus may provide an image by using light-emitting diodes. The uses and structures of display apparatuses have become more diverse and structures that may be bent from an approximately flat state to have a certain angle have also been developed.

A display apparatus may include multiple pixels arranged in a pattern to provide an image. Several layers including an emission layer may be included in the pixels arranged in the pattern. The several layers may be arranged on a substrate in different patterns according to their types.

### SUMMARY

Each layer of a display apparatus may be formed by depositing a deposition material by using a mask having an opening corresponding to a pattern to be formed on a substrate. The deposition material may be deposited in a chamber of a device for manufacturing a display apparatus. After the deposition material is deposited on the substrate, a cleaning material may be injected into the chamber to remove the deposition material remaining in the chamber. A flow rate of the cleaning material may vary according to an area in the chamber, and sufficient cleaning of the deposition material may not be performed in a certain area with a low flow rate.

Additional aspects will be set forth in part in the description which follows and, in part, will be apparent from the description, or may be learned by practice of the presented embodiments.

According to one or more embodiments, a device for manufacturing a display apparatus may include a chamber having inner sides, a susceptor disposed in the chamber, a diffuser facing the susceptor, a shadow frame disposed between the susceptor and the diffuser, a fixing member disposed on at least one of the inner sides of the chamber, and a flow control member disposed on the at least one of the inner sides of the chamber to correspond to the fixing member and including at least a part disposed under the susceptor, wherein the flow control member may be slidable in a direction upon being coupled to the fixing member.

One of the flow control member and the fixing member may include a protrusion protruding in a direction, and another of the flow control member and the fixing member may include a receiving portion in which the protrusion may be inserted.

The flow control member may be coupled to the fixing member by allowing the protrusion to slide into the receiving portion in a direction perpendicular to a protruding direction of the protrusion.

The flow control member may include a first portion contacting the at least one of the inner sides of the chamber, and a second portion protruding in a direction substantially perpendicular to the at least one of the inner sides of the chamber.

An end portion of the second portion may be rounded.

The second portion may overlap the shadow frame.

The flow control member may further include a third portion disposed at an end portion of the second portion, and an upper surface of the third portion may be disposed at a higher position than an upper surface of the second portion.

The at least one of the inner sides of the chamber may include a groove in which at least a part of the fixing member may be inserted.

The fixing member may include a first portion inserted in the groove and partially filling the groove, and a second portion protruding to outside of the groove and coupled to the flow control member.

In a first area adjacent to a corner of the chamber, a space over the flow control member and a space under the flow control member may be in fluid communication.

According to one or more embodiments, a method of manufacturing a display apparatus may include providing a device for manufacturing the display apparatus that includes a chamber that includes inner sides, depositing a deposition material on a substrate in the chamber and using a mask, and cleaning an inside of the chamber with a cleaning material, wherein the device for manufacturing a display apparatus may include a fixing member disposed on at least one of the inner sides of the chamber, and a flow control member disposed in the chamber, the flow control member sliding in a direction upon being coupled to the fixing member, a flow of the cleaning material may be guided by the flow control member during the cleaning of the inside of the chamber.

One of the flow control member and the fixing member may include a protrusion protruding in a direction, and another of the flow control member and the fixing member may include a receiving portion in which the protrusion may be inserted.

The flow control member may be coupled to the fixing member by allowing the protrusion to slide into the receiving portion in a direction perpendicular to a protruding direction of the protrusion.

The flow control member may include a first portion contacting the at least one of the inner sides of the chamber, and a second portion protruding in a direction substantially perpendicular to the at least one of the inner sides of the chamber.

An end portion of the second portion may be rounded.

The flow control member may further include a third portion disposed at an end portion of the second portion, wherein an upper surface of the third portion may be disposed at a higher position than an upper surface of the second portion.

The at least one of the inner sides of the chamber may include a groove in which at least a part of the fixing member may be inserted.

The fixing member may include a first portion inserted in the groove and partially filling the groove, and a second portion protruding to outside of the groove and coupled to the flow control member.

In the cleaning, a flow of the cleaning material may be guided by the flow control member to at least one of corners inside the chamber.

In the cleaning, a flow of the cleaning material between an upper side and a lower side inside the chamber may be substantially performed in at least one of corners inside the chamber.

### BRIEF DESCRIPTION OF THE DRAWINGS

The above and other aspects, features, and advantages of certain embodiments will be more apparent from the following description taken in conjunction with the accompanying drawings, in which:

FIG. 1 is a schematic plan view illustrating a device for manufacturing a display apparatus according to an embodiment;

FIG. 2 is a schematic cross-sectional view illustrating the device for manufacturing a display apparatus taken along line II-II′;

FIG. 3 is a schematic cross-sectional view illustrating the device for manufacturing a display apparatus taken along line III-III′;

FIG. 4 is a perspective view illustrating a flow control member according to an embodiment;

FIG. 5 is a perspective view illustrating a flow control member and a fixing member according to an embodiment;

FIG. 6 is a perspective view illustrating a flow control member and a fixing member from a different angle according to an embodiment;

FIG. 7 is a schematic cross-sectional view illustrating a state where a flow control member and a fixing member may be coupled to each other according to an embodiment;

FIG. 8 is a bottom view illustrating a state where a flow control member and a fixing member may be coupled to each other according to an embodiment;

FIGS. 9 and 10 are perspective views illustrating a state where a flow control member and a fixing member may be coupled to each other according to an embodiment;

FIG. 11 is a schematic cross-sectional schematically illustrating a flow control member, a fixing member, and an inner side of a chamber which may be coupled to each other;

FIG. 12 is a schematic plan view schematically illustrating a device for manufacturing a display apparatus according to an embodiment;

FIG. 13 is a schematic cross-sectional view illustrating a step in the process of a method of manufacturing a display apparatus according to an embodiment;

FIG. 14 is a schematic cross-sectional view illustrating a step in the process of a method of manufacturing a display apparatus according to an embodiment;

FIG. 15A is a schematic plan view illustrating a step in the process of a method of manufacturing a display apparatus according to a first embodiment;

FIG. 15B is a schematic plan view illustrating a step in the process of a method of manufacturing a display apparatus according to a second embodiment;

FIG. 16 is a schematic plan view illustrating a display apparatus manufactured by using a device for manufacturing a display apparatus according to an embodiment; and

FIG. 17 is a schematic cross-sectional view illustrating the display apparatus taken along line XVII-XVII′ of FIG. 12.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc., (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc., may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the inventive concepts. Further, the blocks, parts, and/or modules of some embodiments may be physically combined into more complex blocks, parts, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

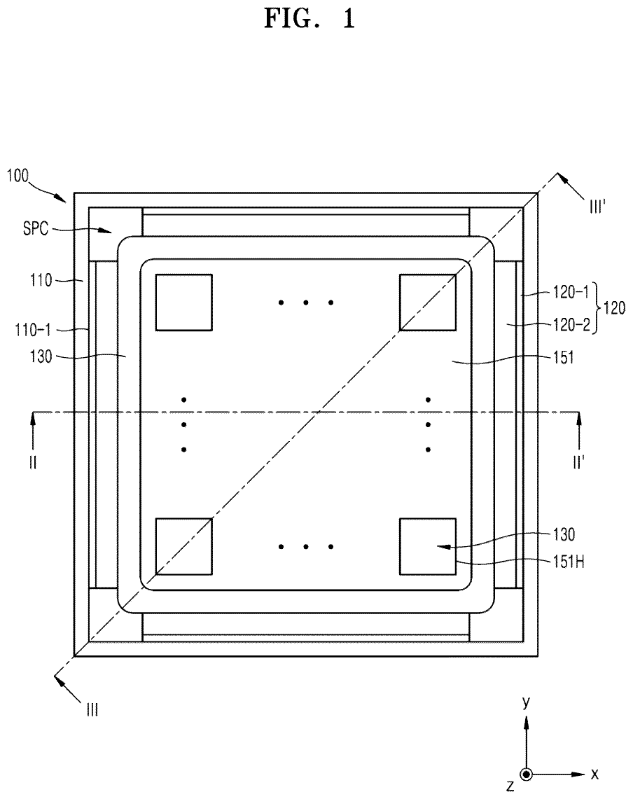

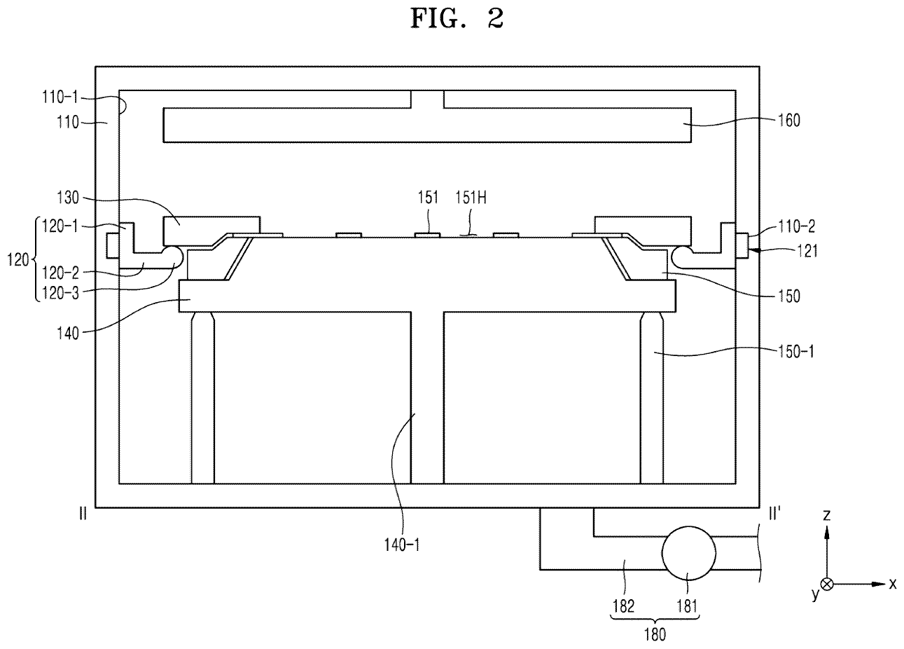

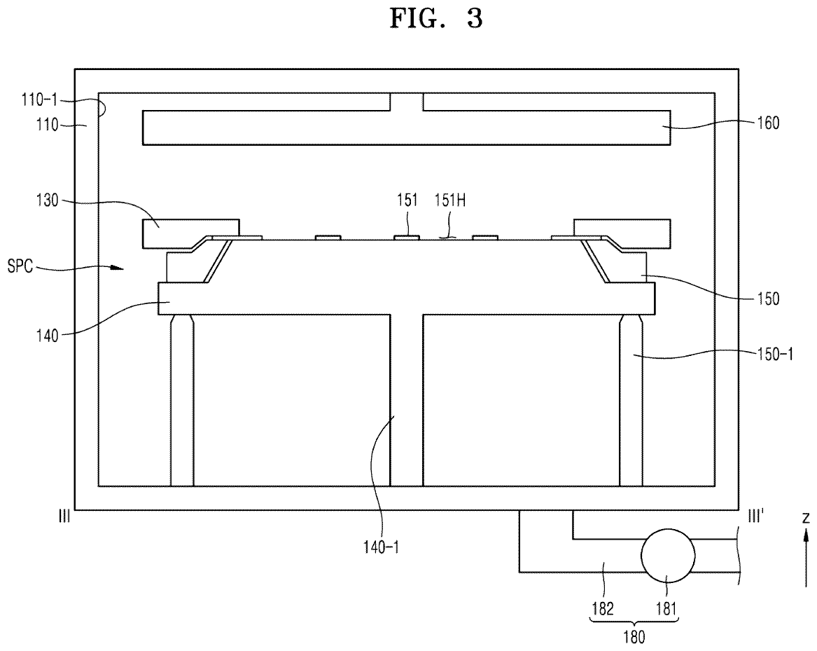

FIG. 1 is a schematic plan view illustrating a device for manufacturing a display apparatus according to an embodiment. FIG. 2 is a schematic cross-sectional view illustrating the device for manufacturing a display apparatus taken along line II-II′. FIG. 3 is a schematic cross-sectional view illustrating the device for manufacturing a display apparatus taken along line III-III′.

Referring to FIGS. 1 to 3, an apparatus 100 for manufacturing a display apparatus may include a chamber 110, a flow control member 120, a fixing member 121, a shadow frame 130, a susceptor 140, a mask support 150, a deposition mask 151, a diffuser 160, and a pressure adjusting part 180.

The chamber 110 may have an inner space, and although not shown in FIGS. 1 to 3, a portion of the chamber 110 may be open. A gate valve may be provided at the open portion of the chamber 110. According to an operation of the gate valve, the open portion of the chamber 110 may be opened or closed.

The flow control member 120 may be disposed (or located) on an inner side 110-1 of the chamber 110 or may be fixed to the inner side 110-1 of the chamber 110. In an embodiment and as shown in FIG. 1, the inside of the chamber 110 may have a substantially quadrangular shape in a plan view, and the flow control member 120 may extend in the same direction as a direction in which the inner side 110-1 of the chamber 110 extends and may be disposed on the inner side 110-1 of the chamber 110. For example, the inner side 110-1 of the chamber 110 may extend in an x direction or a y direction, and the flow control member 120 may also extend entirely in the x direction or the y direction. An x-direction length or a y-direction length of the flow control member 120 may be less than an x-direction length or a y-direction length of the inner side 110-1 of the chamber 110. Accordingly, the flow control member 120 may not be disposed in a certain area in the chamber 110. For example, the flow control member 120 may not be disposed in a first area SPC adjacent to each corner of the chamber 110.

The flow control member 120 may include a first portion 120-1 contacting (e.g., directly contacting) the inner side 110-1 of the chamber 110, a second portion 120-2 protruding substantially perpendicularly from the inner side 110-1 of the chamber 110, and a third portion 120-3 formed at an end portion of the second portion 120-2. In an embodiment, the flow control member 120 may extend entirely in the x direction, and the second portion 120-2 of the flow control member 120 may protrude in a direction perpendicular to the x direction, for example, in the y direction. In an embodiment, the flow control member 120 may extend entirely in the y direction, and the second portion 120-2 of the flow control member 120 may protrude in a direction perpendicular to the y direction, for example, in the x direction. More detailed structures of the first to third portions 120-1, 120-2, and 120-3 of the flow control member 120 will be described below.

The fixing member 121 may be disposed on the inner side 110-1 of the chamber 110. In an embodiment, the fixing member 121 may be fixed to a wall that defines the inner side 110-1 of the chamber 110. In an embodiment, the fixing member 121 may be inserted into the wall that defines the inner side 110-1 of the chamber 110. For example, a groove 110-2 may be formed in the wall that defines the inner side 110-1 of the chamber 110, and the fixing member 121 may be inserted (or received) in the groove 110-2.

The flow control member 120 and the fixing member 121 may be coupled to each other. In an embodiment, the fixing member 121 may be fixed to the inner side 110-1 of the chamber 110, and the flow control member 120 may be coupled to the fixing member 121 to be fixed to the inner side 110-1 of the chamber 110. A method of coupling the flow control member 120 to the fixing member 121 and a method of fixing the fixing member 121 to the inner side 110-1 of the chamber 110 will be described below in detail.

The shadow frame 130 may be disposed on the flow control member 120. The shadow frame 130 may fix the deposition mask 151 together with the mask support 150 by holding the deposition mask 151 between the shadow frame 130 and the mask support 150. The shadow frame 130 may include an opening overlapping the susceptor 140 in a central portion thereof. Although the shadow frame 130 has a substantially quadrangular shape with rounded corners in FIG. 1, the disclosure is not limited thereto. A part of the shadow frame 130 may overlap the flow control member 120. For example, a part of the shadow frame 130 may overlap the third portion 120-3 of the flow control member 120. As another example, the shadow frame 130 may overlap parts of the third portion 120-3 and the second portion 120-2 of the flow control member 120. The shadow frame 130 may be raised or lowered in a z direction by a separate linear actuator (not shown), and thus, an interval between the shadow frame 130 and the mask support 150 and an interval between the shadow frame 130 and the flow control member 120 may be adjusted. In FIG. 2, the shadow frame 130 may be lowered to contact the flow control member 120.

The susceptor 140 may be disposed under the shadow frame 130 and the deposition mask 151. The susceptor 140 may support and heat a substrate during a deposition process. The susceptor 140 may include a separate heat source (not shown) that may heat the substrate disposed on an upper (or a top) surface of the susceptor 140. The susceptor 140 may extend to the chamber 110 through a susceptor support 140-1. For example, the susceptor 140 may be raised or lowered in the z direction by a linear actuator (not shown) separately provided in the susceptor support 140-1.

The mask support 150 may be disposed between the shadow frame 130 and the susceptor 140. The mask support 150 may have an open central portion, like the shadow frame 130. An opening of the shadow frame 130 and an opening of the mask support 150 may overlap the susceptor 140. The mask support 150 may extend to a lifting portion 150-1 that may be disposed under the mask support 150. For example, the mask support 150 may be raised or lowered in the z direction by a linear actuator (not shown) separately provided in the lifting portion 150-1, and thus, an interval between the shadow frame 130 and the mask support 150 may be adjusted. Accordingly, the deposition mask 151 may be held between the shadow frame 130 and the mask support 150.

The deposition mask 151 may be disposed between and held by the shadow frame 130 and the mask support 150. However, the deposition mask 151 may not always be held by the shadow frame 130 and the mask support 150. As an interval between the shadow frame 130 and the mask support 150 may be adjusted in the above manner, the deposition mask 151 may be released. The deposition mask 151 may be loaded into the chamber 110 from the outside or may be replaced. The deposition mask 151 may include multiple openings 151H, and the openings 151H of the deposition mask 151 may define an area where a deposition material is deposited. The disclosure is not limited to a shape or a size of the opening 151H of the deposition mask 151 shown in FIG. 1.

The diffuser 160 may face the deposition mask 151 and the susceptor 140. In an embodiment, a deposition material may be accommodated in the diffuser 160 or may be supplied from the outside. In an embodiment, the diffuser 160 may vaporize or sublimate the deposition material by applying heat to the deposition material. In an embodiment, the diffuser 160 may receive a gaseous deposition material from the outside. In an embodiment, the diffuser 160 may include a nozzle through which the gaseous deposition material may be diffused into the chamber 110. The diffuser 160 may be fixed to the inside of the chamber 110 or may be disposed in the chamber 110 to linearly move in a direction (e.g., single direction). For convenience of explanation, the following will be described in detail assuming that the diffuser 160 may be fixed to the inside of the chamber 110.

The pressure adjusting part 180 may extend to the chamber 110 to adjust pressure in the chamber 110. For example, the pressure adjusting part 180 may adjust pressure in the chamber 110 to be equal or similar to atmospheric pressure. Also, the pressure adjusting part 180 may adjust pressure in the chamber 110 to be equal or similar to a vacuum state.

The pressure adjusting part 180 may include a connection pipe 182 connected to the chamber 110 and a pump 181 provided in the connection pipe 182. According to an operation of the pump 181, external air may be introduced through the connection pipe 182 or gas in the chamber 110 may be discharged to the outside through the connection pipe 182.

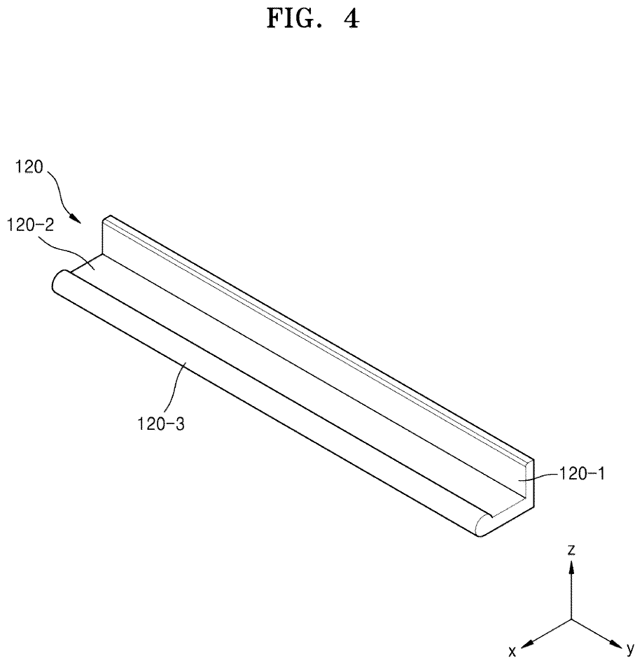

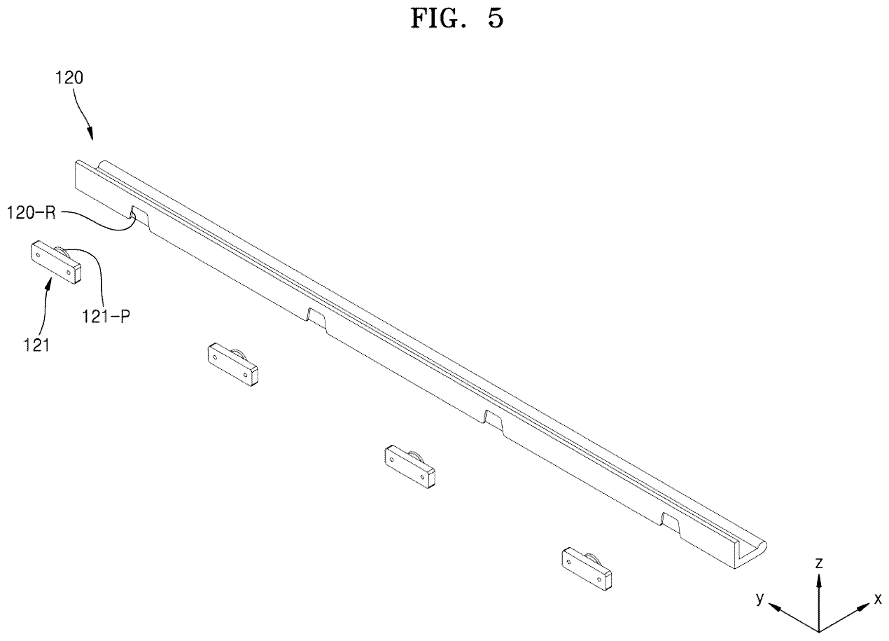

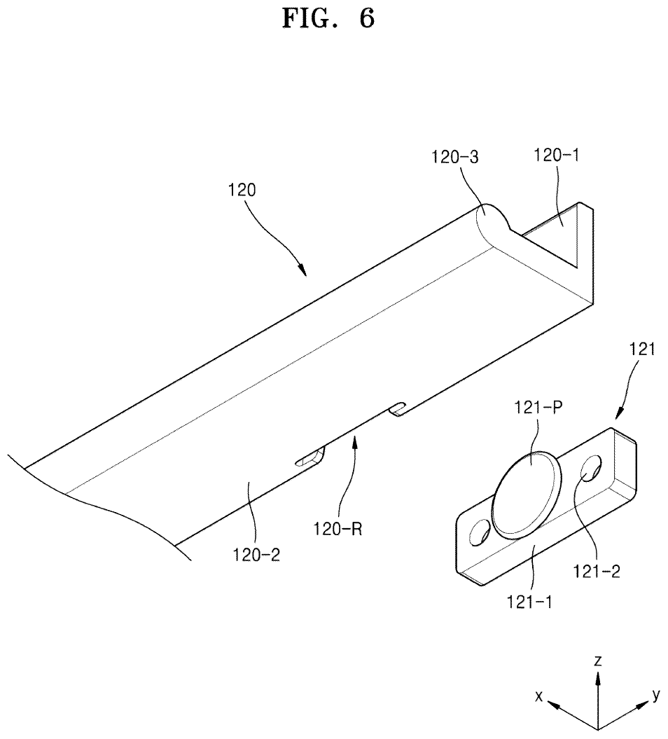

FIG. 4 is a perspective view illustrating a flow control member according to an embodiment. FIG. 5 is a perspective view illustrating a flow control member and a fixing member according to an embodiment. FIG. 6 is a perspective view illustrating a flow control member and a fixing member from a different angle according to an embodiment.

Referring to FIGS. 4 to 6, the flow control member 120 may have a shape elongated entirely in a direction. For example, the flow control member 120 may have a shape extending entirely in the y direction. The flow control member 120 may protrude in a direction perpendicular to the extending direction. For example, the flow control member 120 may extend entirely in the y direction and may protrude in the x direction that may be substantially perpendicular to the y direction. An x-direction length of a part of the flow control member 120 protruding in the x direction may be less than a y-direction length, that is, an overall length of the flow control member 120 extending in the y direction. In other words, the flow control member 120 may have a roughly L-shaped cross section extending in a direction (e.g., the y direction). However, the flow control member 120 may not necessarily extend in the y direction and protrude in the x direction. In another embodiment, the flow control member 120 may extend in the x direction and may protrude in the y direction. For convenience of explanation, the following will be described in detail assuming that the flow control member 120 extends in the y direction and protrudes in the x direction.

The flow control member 120 may include the first to third portions 120-1, 120-2, and 120-3. In a plan view or in case of being viewed from a y-direction side, the first portion 120-1 of the flow control member 120 may extend in a direction, for example, the z direction. The first portion 120-1 may be a portion contacting the inner side 110-1 (see FIG. 2) of the chamber as described with reference to FIGS. 1 to 3. In a plan view or in case of being viewed from a y-direction side, the second portion 120-2 of the flow control member 120 may extend in a direction, for example, the x direction. In other words, the second portion 120-2 of the flow control member 120 may protrude from the first portion 120-1 in a direction (e.g., the x direction) substantially perpendicular to a direction (e.g., the z direction) in which the first portion 120-1 extends. The third portion 120-3 of the flow control member 120 may be formed at an end portion of the second portion 120-2, for example, an end portion in the x direction. The third portion 120-3 may be a rounded end portion of the second portion 120-2. In an embodiment, a thickness (or a z-direction length) of the third portion 120-3 may be greater than a thickness (or a z-direction length) of the second portion 120-2. In an embodiment, an upper surface (e.g., a surface facing a +z direction) of the third portion 120-3 may be disposed at a higher position than an upper surface (or a surface facing the +z direction) of the second portion 120-2. The first to third portions 120-1, 120-2, and 120-3 of the flow control member 120 may be separately formed and then coupled, or may be integral with each other. As described above, the flow control member 120 may extend entirely in a direction, for example, the y direction, and the first to third portions 120-1, 120-2, and 120-3 of the flow control member 120 may also extend in a direction, for example, the y direction.

The flow control member 120 may include a receiving portion 120-R formed in the first portion 120-1. The receiving portion 120-R may be a groove formed in the first portion 120-1 of the flow control member 120 to receive a protrusion 121-P of the fixing member 121 described below. Multiple receiving portions 120-R may be provided in a flow control member (e.g., single flow control member) 120. In an embodiment and as shown in FIG. 5, a flow control member 120 may include, for example, four receiving portions 120-R. However, the disclosure is not necessarily limited to the number. The receiving portion 120-R may be disposed on a surface opposite to a surface on which the second portion 120-2 may be disposed from among several surfaces of the first portion 120-1 of the flow control member 120. For example, from among surfaces of the first portion 120-1, the second portion 120-2 may protrude from a surface facing an +x direction, and the receiving portion 120-R may be formed in a surface facing a −x direction.

As shown in FIG. 5, fixing member 121 may extend entirely in a direction, for example, the y direction, like the flow control member 120. A length of the fixing member 121 extending along the above direction, for example, a y-direction length, may be less than a y-direction length of the flow control member 120. Accordingly and as shown in FIG. 5, a flow control member 120 may be paired with multiple fixing members 121.

As shown in FIG. 6, the fixing member 121 may include a main body 121-1, the protrusion 121-P, and multiple, for example two openings 121-2 formed in the main body 121-1. Referring to FIG. 2 together, a part of the fixing member 121 inserted into a wall defining the inner side 110-1 of the chamber 110 may be the main body 121-1 of the fixing member 121. The groove 110-2 formed in the wall may be formed to receive the main body 121-1 of the fixing member 121. In case of being viewed from the x direction, the main body 121-1 of the fixing member 121 has a quadrangular shape with rounded corners in FIGS. 5 and 6, a shape of the main body 121-1 may be changed in various ways. The openings 121-2 formed in the main body 121-1 of the fixing member 121 may be holes in which means (e.g., screws BT) for fixing the fixing member 121 to the inner side 110-1 of the chamber 110 may be disposed. The openings 121-2 of the fixing member 121 may pass through the main body 121-1.

The protrusion 121-P of the fixing member 121 may protrude in a direction, for example the x direction, from the main body 121-1. In an embodiment, the protrusion 121-P may have a substantially coin shape, and a diameter of the coin shape may be greater than a z-direction length of the main body 121-1 of the fixing member 121. The portion having the coin shape may extend to the main body 121-1 through a connecting portion having a diameter less than the diameter of the coin shape. In another embodiment, the portion having the coin shape and the connecting portion may collectively constitute the protrusion 121-P.

The protrusion 121-P may be inserted in the receiving portion 120-R of the flow control member 120. The receiving portion 120-R of the flow control member 120 and the protrusion 121-P of the fixing member 121 may be engaged with each other in case that the protrusion 121-P is inserted into the receiving portion 120-R. For example and as shown in FIGS. 5 and 6, the protrusion 121-P may have a coin shape as described above, and the receiving portion 120-R may be a slot formed to receive the coin shape. In an embodiment, the openings 121-2 of the fixing member 121 may be symmetrically arranged with respect to the protrusion 121-P of the fixing member 121. For example, the openings 121-2 of the fixing member 121 may be symmetrically arranged along the y direction with respect to the protrusion 121-P.

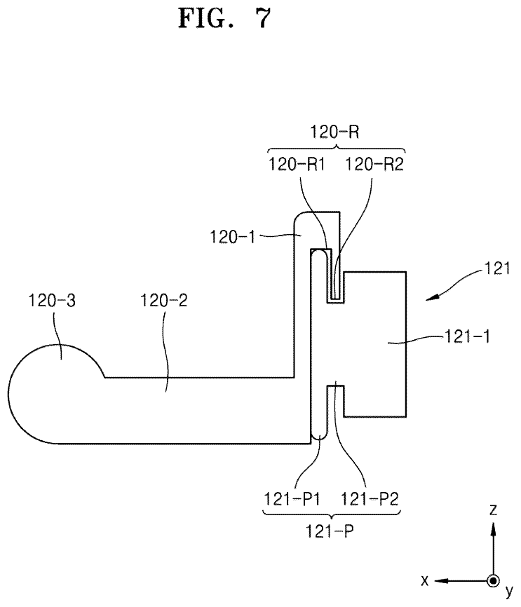

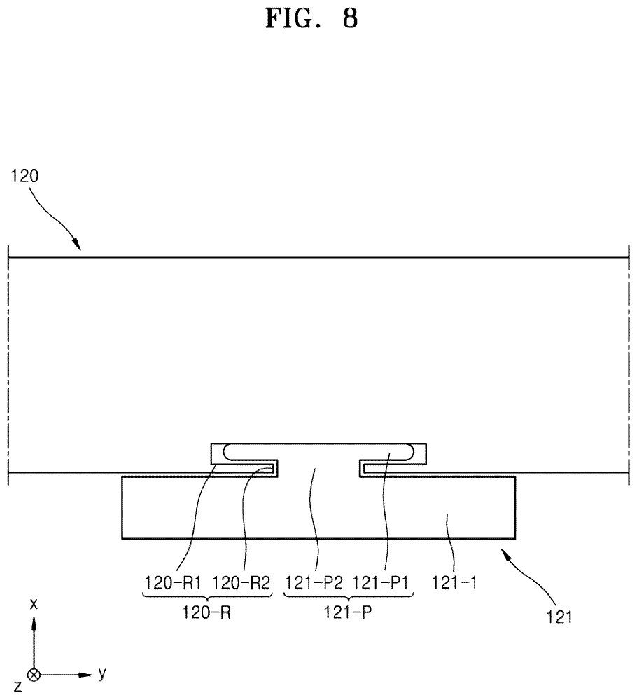

FIG. 7 is a schematic cross-sectional view illustrating a state where a flow control member and a fixing member may be coupled to each other according to an embodiment. FIG. 8 is a bottom view illustrating a state where a flow control member and a fixing member may be coupled to each other according to an embodiment.

Referring to FIGS. 7 and 8, the flow control member 120 and the fixing member 121 may extend to each other through engagement between the receiving portion 120-R and the protrusion 121-P.

The receiving portion 120-R of the flow control member 120 may be a groove formed in the first portion 120-1 of the flow control member 120. For example, the receiving portion 120-R may extend along the z direction and the y direction and may be formed in the first portion 120-1. A lower surface (or a −z direction surface) of the first portion 120-1 of the flow control member 120 may be open due to the receiving portion 120-R. The receiving portion 120-R may not pass through the first portion 120-1 in the z direction. Accordingly, an upper surface (or a +z direction surface) of the first portion 120-1 of the flow control member 120 may not be open. In other words, a z-direction length of the receiving portion 120-R may be less than a z-direction length of the first portion 120-1.

A z-direction length of the receiving portion 120-R may vary along the x direction. In an embodiment, a z-direction length of the receiving portion 120-R may increase toward the +x direction. For example, referring to FIG. 7, the receiving portion 120-R may include a first receiving portion 120-R1 and a second receiving portion 120-R2 adjacent to each other. Relatively, a z-direction length of the first receiving portion 120-R1 may be greater than a z-direction length of the second receiving portion 120-R2. In case of being viewed from the y direction, the receiving portion 120-R may include a z-direction stepped portion due to a +z-direction length difference between the first receiving portion 120-R1 and the second receiving portion 120-R2. Due to the stepped portion, the first portion 120-1 of the flow control member 120 may be formed to insert or hold the protrusion 121-P of the fixing member 121 therein.

Likewise, a y-direction length of the receiving portion 120-R may vary along the x direction. In an embodiment, a y-direction length of the receiving portion 120-R may increase toward the +x direction. For example, referring to FIG. 8, a y-direction length of the first receiving portion 120-R1 may be greater than a y-direction length of the second receiving portion 120-R2. In case of being viewed from a −z direction, the receiving portion 120-R may have a bottleneck shape due to a y-direction length difference between the first receiving portion 120-R1 and the second receiving portion 120-R2. Due to the bottleneck shape, the first portion 120-1 of the flow control member 120 may be formed to insert or hold the protrusion 121-P of the fixing member 121 therein.

The protrusion 121-P of the fixing member 121 may be inserted into the receiving portion 120-R of the flow control member 120. For example, the protrusion 121-P may include a first protrusion 121-P1 having a substantially coin shape substantially matching the first receiving portion 120-R1, and the first protrusion 121-P1 may be inserted into the first receiving portion 120-R1. A diameter (e.g., a z-direction length) of the first protrusion 121-P1 may be close to a z-direction length of the first receiving portion 120-R1. A z-direction length (or a diameter) of the protrusion 121-P may vary along the x direction, like the receiving portion 120-R. In an embodiment, a diameter (or a z-direction length) of the protrusion 121-P may increase toward the +x direction. For example, the protrusion 121-P may include the first protrusion 121-P1 and a second protrusion 121-P2 that connects the first protrusion 121-P1 to the main body 121-1. Referring to FIGS. 7 and 8, a diameter of the first protrusion 121-P1 may be greater than a diameter of the second protrusion 121-P2. The first protrusion 121-P1 may overlap the first receiving portion 120-R1, and the second protrusion 121-P2 may overlap the second receiving portion 120-R2. In other words, the first protrusion 121-P1 may be inserted in the first receiving portion 120-R1, and the second protrusion 121-P2 may be inserted in the second receiving portion 120-R2. Through the above structure, the protrusion 121-P may be inserted into the receiving portion 120-R, and the first portion 120-1 of the flow control member 120 where the receiving portion 120-R is formed may substantially hold the protrusion 121-P.

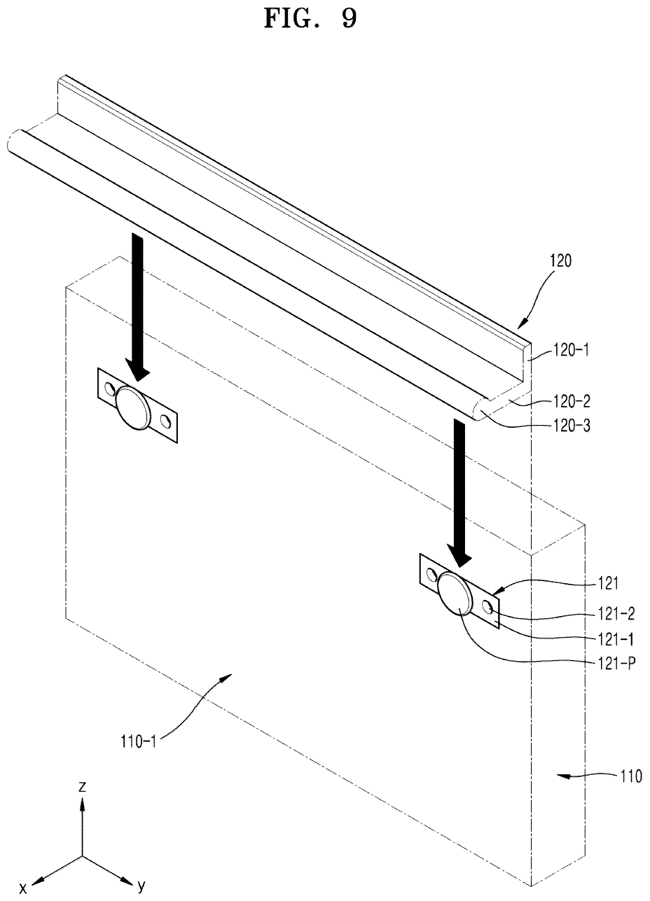

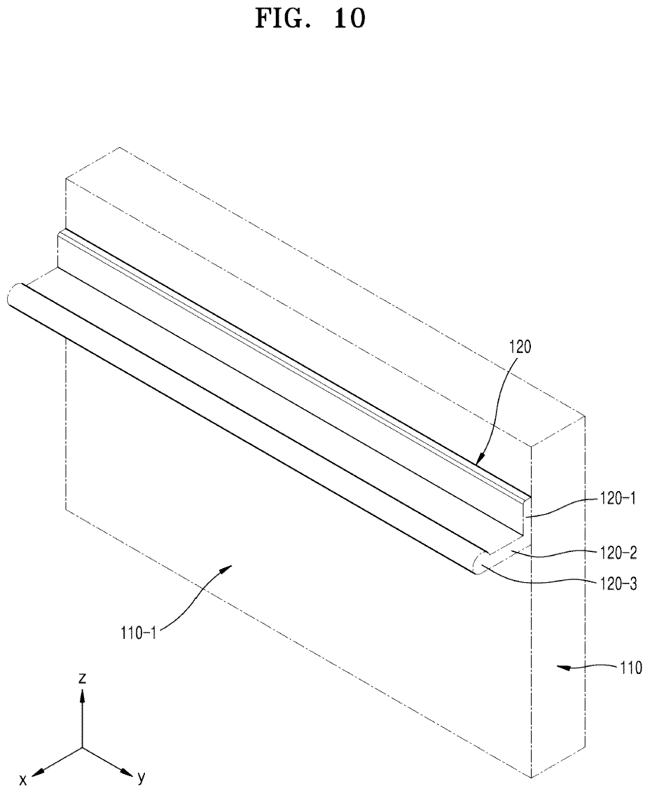

FIGS. 9 and 10 are perspective views illustrating a state where a flow control member and a fixing member may be coupled to each other according to an embodiment.

Referring to FIGS. 9 and 10, the fixing members 121 may be fixed to the inner side 110-1 of the chamber 110. The flow control member 120 may be translated in a direction, for example the −z direction. In an embodiment, the flow control member 120 and the fixing member 121 may be aligned so that the protrusion 121-P of the fixing member 121 may be inserted into the receiving portion 120-R (see FIG. 8) of the flow control member 120. The flow control member 120 may include multiple receiving portions, and the receiving portions may be arranged at certain intervals. The fixing members 121 may be disposed on the inner side 110-1 of the chamber 110 and may be arranged at similar intervals as those of the receiving portions. In an embodiment, a surface (e.g., single surface) of the flow control member 120, for example, a surface of the first portion 120-1 of the flow control member 120 facing the −x direction, may be disposed on the same plane as the inner side 110-1 of the chamber 110 facing the +x direction. Accordingly and as shown in FIG. 10, in case that the flow control member 120 is coupled to the fixing member 121, the first portion 120-1 of the flow control member 120 may contact (e.g., directly contact) the inner side 110-1 of the chamber 110.

Due to the above structure, the flow control member 120 may be attached to and detached from the fixing member 121 through a simple operation (e.g., translation), thereby facilitating maintenance of the flow control member 120.

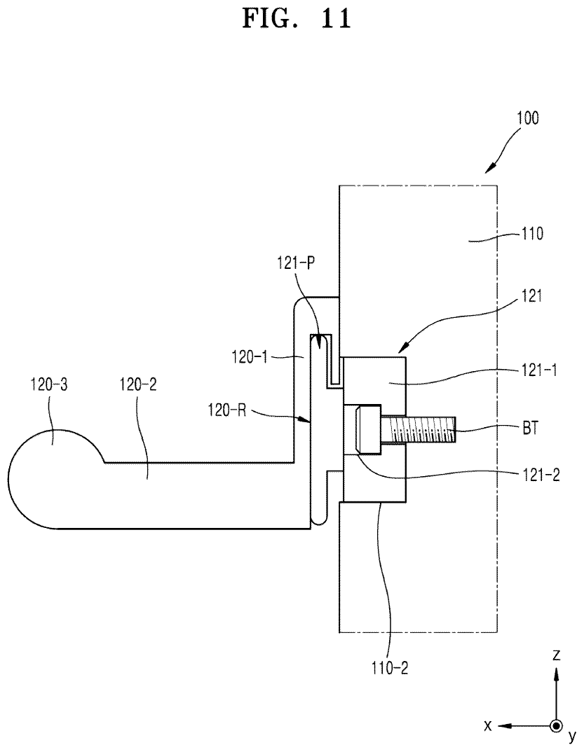

FIG. 11 is a schematic cross-sectional view schematically illustrating a flow control member, a fixing member, and an inner side of a chamber which may be coupled to each other.

Referring to FIG. 11, the coupling of the flow control member 120 and the fixing member 121 has been described, and thus the following will focus on the coupling of the fixing member 121 to the inner side 110-1 of the chamber 110.

A wall defining the inner side 110-1 of the chamber 110 may include the groove 110-2 in which a part of the fixing member 121 may be inserted. For example, the wall may include the groove 110-2 in which the main body 121-1 of the fixing member 121 may be inserted. The main body 121-1 of the fixing member 121 may be inserted in the groove 110-2, and the protrusion 121-P may extend to the outside of the groove, for example, beyond a surface of the inner side 110-1 of the chamber 110. In an embodiment, a depth (or an x-direction length) of the groove 110-2 may be greater than an x-direction length of the main body 121-1 of the fixing member 121. The main body 121-1 of the fixing member 121 may only partially fill the groove 110-2. A surface of the fixing member facing the +x direction may be more recessed than a surface of the inner side 110-1 of the chamber 110 facing the +x direction. Accordingly, the main body 121-1 of the fixing member 121 may be spaced apart from the first portion of the flow control member 120 contacting (e.g., directly contacting) the inner side 110-1 of the chamber 110.

The groove 110-2 may include a screw hole extending further in the +x direction. The screw hole may have a screw thread on an inner surface thereof and may be formed to receive a screw of a certain size therein.

The fixing member 121 may include the opening 121-2 extending in the x direction. The opening 121-2 may be formed to receive a screw BT therein. A part of the opening 121-2 may have substantially the same diameter as that of a screw BT of a certain size so that the head of the screw BT may be inserted. Another part of the opening 121-2 may have a diameter less than the diameter of the portion in which the head of the screw BT may be inserted, and a screw thread may be formed on an inner surface of the main body 121-1 of the fixing member 121 in the corresponding portion. In an embodiment, another part of the opening 121-2 and the screw hole of the groove 110-2 may be aligned, and may have the same diameter.

A screw BT may be disposed to simultaneously pass through the opening 121-2 of the fixing member 121 and the screw hole of the groove 110-2 of the inner side 110-1 of the chamber 110. The screw BT may be engaged with the screw threads of the opening 121-1 and the screw hole to fix the fixing member 121 to the groove 110-2. A depth of the opening 121-2 may be sufficient so that the head of the screw BT does not protrude out of the opening 121-2.

Through the above structure, the fixing member 121 may be configured so that only the protrusion 121-P protrudes from the inner side 110-1 of the chamber 110 and the fixing member 121 may be coupled to the chamber 110.

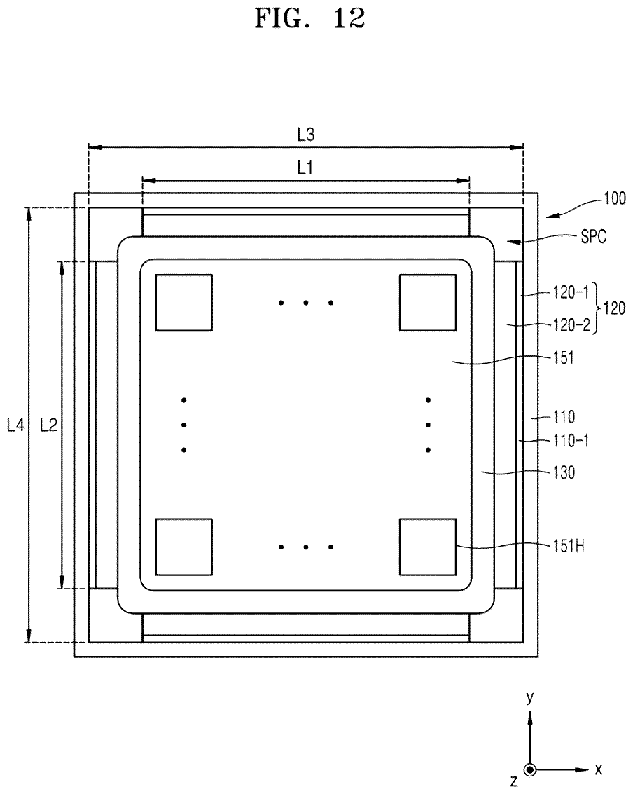

FIG. 12 is a schematic plan view schematically illustrating a device for manufacturing a display apparatus according to an embodiment.

Referring to FIG. 12, an x-direction length of the flow control member 120 disposed parallel to the x direction from among the flow control members 120 provided in the chamber 110 may be defined as a first length L1. Likewise, a y-direction length of the flow control member 120 disposed parallel to the y direction from among the flow control members 120 provided in the chamber 110 may be defined as a second length L2. An x-direction length of the inner side 110-1 parallel to the x direction from among the inner sides 110-1 of the chamber 110 may be defined as a third length L3. Likewise, an x-direction length of the inner side 110-1 parallel to the x direction from among the inner sides 110-1 of the chamber 110 may be defined as a fourth length L4.

Although the chamber 110 has a substantially square shape, so that the third length L3 and the fourth length L4 may be the same in FIG. 12, the disclosure is not limited thereto. In an embodiment, the fourth length L4 may be greater than the third length L3. In an embodiment, the third length L3 may be greater than the fourth length L4. The following will be described in detail assuming that that the fourth length L4 may be greater than the third length L3, so that the fourth length L4 may be a length of a long side and the third length L3 may be a length of a short side.

In an embodiment, the first length L1 may be about 70% to about 80% of the third length L3. In an embodiment, the first length L1 may be about 75% to about 80% of the third length L3. In an embodiment, the first length L1 may be about 80% of the third length L3.

In an embodiment, the second length L2 may be about 70% to about 89% of the fourth length L4. In an embodiment, the second length L2 may be about 80% to about 89% of the fourth length L4. In an embodiment, the second length L2 may be about 85% to about 89% of the fourth length L4. In an embodiment, the second length L2 may be about 89% of the fourth length L4.

Due to the above structure, the flow control member 120 may not be disposed on a part of the inner side 110-1 of the chamber 110. For example, the flow control member 120 may not be disposed in the first area SPC described with reference to FIG. 1.

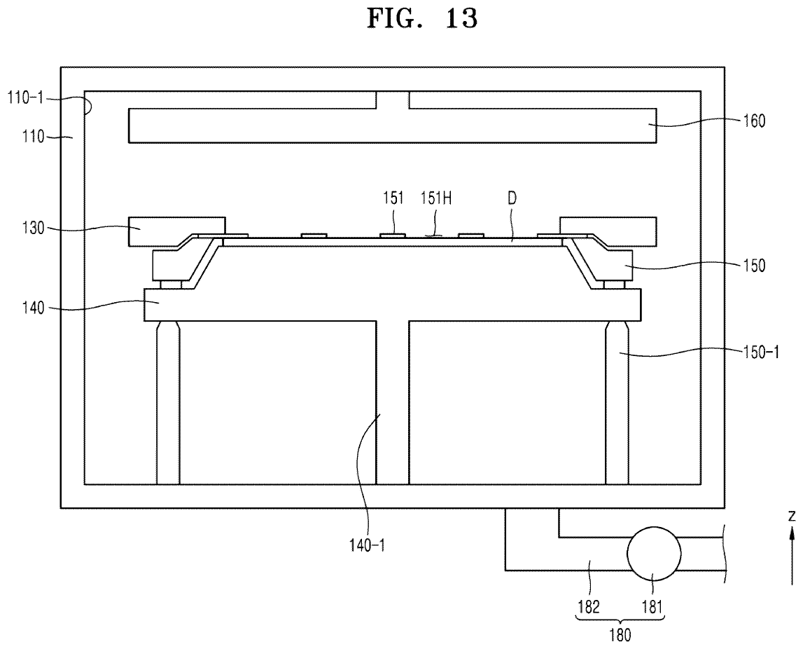

FIG. 13 is a schematic cross-sectional view illustrating a step (e.g., single step) in the process of a method of manufacturing a display apparatus according to an embodiment.

Referring to FIG. 13, a step of depositing a deposition material on a display substrate D is illustrated. First, in case that the pressure adjusting part 180 makes the inside of the chamber the same as or similar to atmospheric pressure, the display substrate D may be loaded from the outside of the chamber 110 into the chamber 110. The display substrate D may be loaded into the chamber 110 in various ways. For example, the display substrate D may be loaded into the chamber 110 from the outside of the chamber 110 through a robot arm or the like disposed outside the chamber 110.

The deposition mask 151 may be disposed in the chamber 110 as shown in FIG. 13. For example, the deposition mask 151 may be held between the shadow frame 130 and the mask support 150. In an embodiment, the deposition mask 151 may be loaded from the outside of the chamber 110 into the chamber 110 like the display substrate D. For convenience of explanation, the following will be described in detail assuming that, in a state where the deposition mask 151 may be disposed in the chamber 110, only the display substrate D may be loaded from the outside of the chamber 110 into the chamber 110.

In case that the display substrate D is loaded into the chamber 110, the display substrate D may be placed on the susceptor 140. A vision part (not shown) that is separately provided may photograph a position of the deposition mask 151, and the display substrate D and the deposition mask 151 may be aligned through a controller by finely adjusting positions of the display substrate D and the deposition mask 151.

In case that the display substrate D is loaded into the chamber 110, the deposition mask 151 may be held between the shadow frame 130 and the mask support 150. In an embodiment, the deposition mask 151 may be sufficiently spaced apart from the susceptor 140 so that the display substrate D may be disposed between the deposition mask 151 and the susceptor 140. To this end, the shadow frame 130 and the mask support 150 may also be sufficiently spaced apart from the susceptor 140. After the display substrate D is loaded into the chamber 110 so that it is disposed between the deposition mask 151 and the susceptor 140, and is aligned with the deposition mask 151, the shadow frame 130, the mask support 150, and the deposition mask 151 may be lowered together (or moved in the −z direction). Accordingly, the deposition mask 151 may be in close contact with the display substrate D. The display substrate D may contact an upper surface of the susceptor 140.

The pump 181 may evacuate the chamber 110 and maintain pressure in the chamber 110 to be equal or similar to a vacuum state by sucking gas in the chamber 110 and discharging the gas to the outside.

A deposition step may now be performed. In an embodiment, the deposition step may be performed by using chemical vapor deposition (CVD). The diffuser 160 may operate to diffuse a deposition material in a gaseous state or a vapor state inside the chamber 110.

During or after the deposition step, a heat source (not shown) of the susceptor 140 may heat the susceptor 140 and may heat the display substrate D contacting the susceptor 140. A part of a surface of the display substrate D overlapping the opening 151H of the deposition mask 151 may contact the deposition material diffused by the diffuser 160 inside the chamber 110. The deposition material may cause a chemical reaction with or on the surface of the display substrate D, and a film may be formed on the display substrate D overlapping the opening 151H of the deposition mask 151. The deposition mask 151 may provide a deposition area identical or similar to a deposition area (e.g., predetermined or selectable deposition area). The above operation may be repeatedly performed on multiple display substrates D.

After the deposition process is performed, the deposition material entirely diffused into the chamber 110 may be seated (or deposited) on surfaces of elements inside the chamber 110. For example, a part of the deposition material may be seated on a surface of the deposition mask 151, the shadow frame 130, the mask support 150, and/or the susceptor 140. The seated deposition material may remain on the surfaces of the elements in the chamber 110 without being discharged from the chamber 110 in case that gas in the chamber 110 is removed through the pressure adjusting part 180. Accordingly, a cleaning process of removing the seated deposition material from the chamber 110 may be required. The cleaning process may include a process of separating the seated deposition material from the surfaces of the elements in the chamber 110 and discharging the deposition material to the outside of the chamber 110.

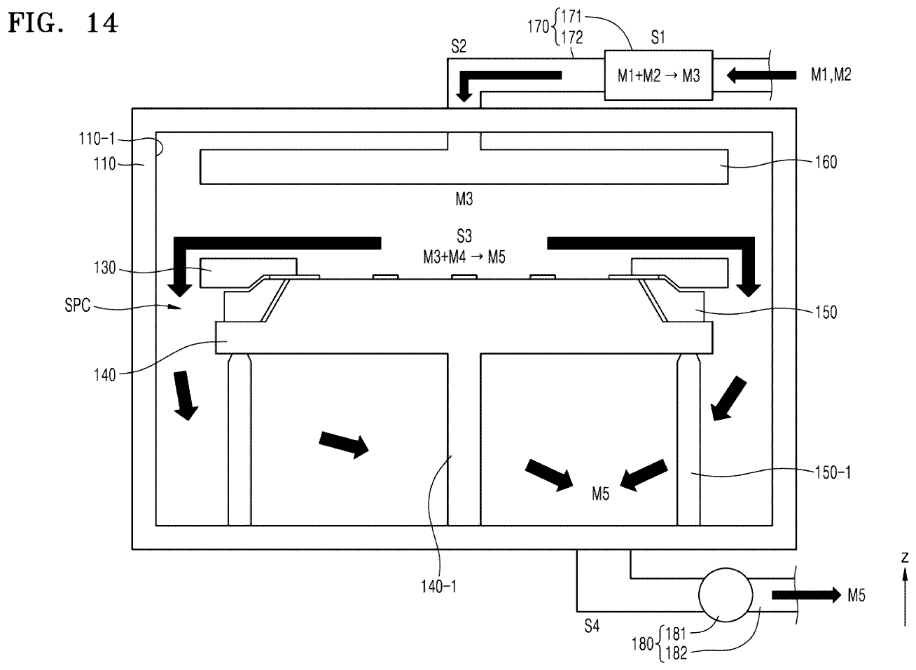

FIG. 14 is a schematic cross-sectional view illustrating a step in the process of a method of manufacturing a display apparatus according to an embodiment.

Referring to FIG. 14 and after a deposition step, a step of cleaning the inside of the chamber 110 is illustrated. First a cleaning material injection part 170 may be provided from outside the chamber 110. The cleaning material injection part 170 may include a plasma chamber 171 and an injection pipe 172.

In a first step S1, a first material M1 and a second material M2 may be introduced into the plasma chamber 171 during a cleaning step. In an embodiment, the first material M1 may be argon (Ar), and the second material M2 may be nitrogen trifluoride (NF₃). After the first material M1 and the second material M2 are introduced into the plasma chamber 171, a voltage may be applied to the plasma chamber 171 to convert the first material M1 into a plasma state. The first material M1 in a plasma state may react with the second material M2 to generate a third material M3 in a plasma state. In an embodiment, the third material M3 may be fluorine (F) in a plasma state. The third material M3 may be a cleaning material used to clean the inside of the chamber 110.

In a second step S2, the third material M3 may be introduced into the chamber 110 through the injection pipe 172. In an embodiment, the injection pipe 172 may extend to the diffuser 160, and the third material M3 may be diffused into the chamber 110 through the diffuser 160. In an embodiment, the injection pipe 172 may extend to a separate path and device to diffuse the third material M3 into the chamber 110.

In a third step S3, the third material M3 may react with a fourth material M4 to generate a fifth material M5. The fourth material M4 may be a deposition material in a solid state remaining in the chamber 110, the third material M3 may be a cleaning material in a plasma state, and the fifth material M5 may be a material in a gaseous state. In an embodiment, the fourth material M4 may be silicon oxynitride (SiON) or silicon nitride (SiNₓ), and the fifth material M5 may be silicon tetrafluoride (SiF₄). The fifth material M5 in a gaseous state may freely flow in the chamber 110 and may be pumped and discharged to the outside of the chamber 110. Hereinafter, in case that the third material M3 is combined with the fourth material M4 to form the fifth material M5, it is expressed as the third material M3 cleaning the fourth material M4.

In a fourth step S4, the fifth material M5 may be discharged to the outside of the chamber 110 through the pressure adjusting part 180 connected to the chamber 110. The fifth material M5 may flow by bypassing elements in the chamber 110, such as the shadow frame 130, the mask support 150, and the susceptor 140. For example, the fifth material M5 may flow in a horizontal direction perpendicular to the z direction toward the inner side 110-1 of the chamber 110, and then may flow substantially along the z direction toward the connection pipe 182 of the pressure adjusting part 180.

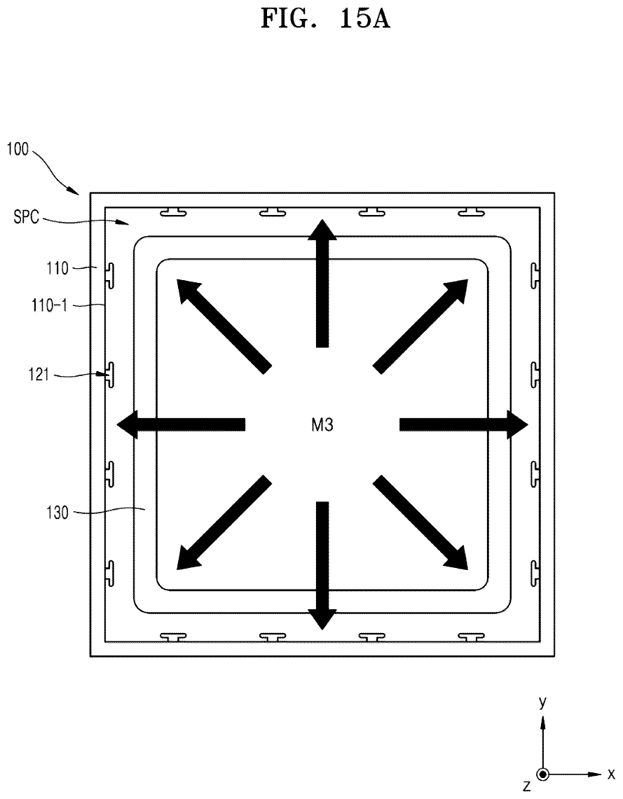

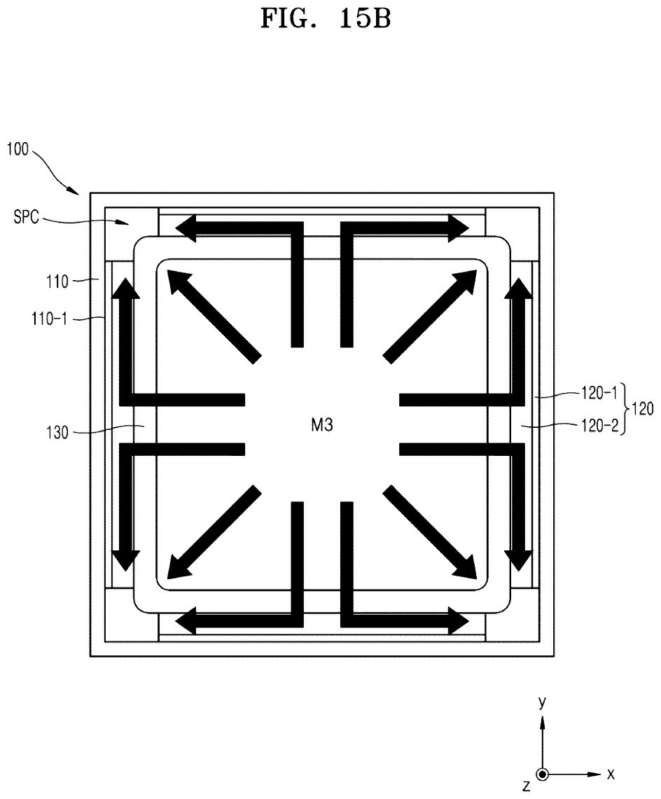

FIG. 15A is a schematic plan view illustrating a step in the process of a method of manufacturing a display apparatus according to a first embodiment. FIG. 15B is a schematic plan view illustrating a step (e.g., single step) in the process of a method of manufacturing a display apparatus according to a second embodiment.

In FIGS. 15A and 15B, a diffusion path of the third material M3 that is a cleaning material may be marked by an arrow. A difference between the first embodiment of FIG. 15A and the second embodiment of FIG. 15B is that the flow control member 120 may not be provided in the chamber 110 in the first embodiment while the flow control member 120 may be provided in the chamber 110 in the second embodiment. A diffusion path of the third material M3 may vary according to whether the flow control member 120 is provided.

Referring to FIGS. 14 and 15A together, the third material M3 may begin to be diffused from a central portion of the chamber 110. Because the shadow frame 130, the mask support 150, and the susceptor 140 may be disposed at the central portion of the chamber 110, the third material M3 may not be diffused in the −z direction at the central portion of the chamber 110 but may be diffused in a direction substantially perpendicular to the z direction toward an inner wall of the chamber 110. While the third material M3 is diffused toward the inner wall of the chamber 110, the third material M3 may clean the fourth material M4 formed on the inner wall of the chamber 110.

Diffusion rates of the third material M3 starting from the central portion of the chamber 110 may be the same in all directions. Accordingly, a diffusion rate of the third material M3 along the x direction or the y direction and a diffusion rate of the third material M3 along a direction oblique to the x direction or the y direction may be the same. For example, a diffusion rate of the third material M3 toward the inner side 110-1 of the chamber 110 and a diffusion rate of the third material M3 toward a corner (or first area SPC) of the chamber 110 may be the same. Because the inside of the chamber 110 has a substantially quadrangular shape, a distance from the central portion of the chamber 110 to the corner (or first area SPC) of the chamber 110 may be greater than a distance from the central portion of the chamber 110 to the inner side 110-1 of the chamber 110. Accordingly, a time taken for the third material M3 diffused at the same speed to reach the corner (or first area SPC) of the chamber 110 may be greater than a time taken for the third material M3 to reach the inner side 110-1 of the chamber 110. Accordingly, due to a time taken for the third material M3 to reach the corner (or first area SPC) of the chamber 110, a final completion time of cleaning may increase even in case that the third material M3 reaches the inner side 110-1 of the chamber 110 and cleaning is completed.

Referring to FIGS. 14 and 15B together, unlike in the first embodiment, the flow control member 120 may be provided on the inner side 110-1 of the chamber 110 in the second embodiment. Because an x-direction or y-direction length of the flow control member 120 may be less than an x-direction or y-direction length of the inner side 110-1 of the chamber 110, the flow control member 120 may not be disposed at a corner (or first area SPC) of the chamber 110.

In the second embodiment, in case that the third material M3 diffused in the x direction or the y direction reaches an inner wall of the chamber 110, the third material M3 may not be directed in the −z direction, which is unlike the first embodiment. Diffusion of the third material M3 in the −z direction may be blocked by the flow control member 120, and a diffusion path of the third material M3 may be bent in a direction. For example, a diffusion direction of the third material M3 flowing along the x direction may be changed to a +y direction or a −y direction, and a diffusion direction of the third material M3 flowing along the y direction may be changed to the +x direction or the −x direction. The third material M3 whose diffusion direction is changed may be diffused to the corner (or first area SPC) of the chamber 110 along the flow control member 120. The third material M3 reaching an area adjacent to the corner (or first area SPC) of the chamber 110, or the first area SPC, may flow in the −z direction together with the fifth material M5.

In case that the third material M3 is guided to the corner (or first area SPC) of the chamber 110 by using the flow control member 120 as in the second embodiment, the amount of the third material M3 reaching the corner (or first area SPC) of the chamber 110 may increase. Accordingly, the area adjacent to the corner (or first area SPC) of the chamber 110 may be cleaned faster, and as a result, a total completion time of cleaning may be reduced compared to the first embodiment.

Some indexes in cleaning the chamber 110 are divided into the first embodiment and the second embodiment and are compared.

TABLE 1

| | First embodiment | Second embodiment |
|---|---|---|
| Category | (FIG. 15A) | (FIG. 15B) |
| Cleaning time | 850 | 595 |
| (sec) | | |
| Cleaning time per substrate | 60 | 58 |
| (sec) | | |
| Monthly substrate production | 165,000 | 172,700 |
| quantity | | |
| (Units) | | |

Referring to Table 1, a cleaning time refers to a time required to completely clean the inside of the chamber 110. A cleaning time per substrate may be obtained by dividing a cleaning time by the number of display substrates that may be produced by using a device for manufacturing a display apparatus per cleaning, and may refer to a time required to produce a display substrate (e.g., single display substrate) and completely remove a deposition material remaining in the chamber 110. A monthly substrate production quantity refers to the number of display substrates that may be produced each month in case that production of the display substrates and cleaning of the chamber 110 are repeated.

A cleaning time of the first embodiment may be about 850 seconds. A cleaning time of the second embodiment may be about 595 seconds. Accordingly, the cleaning time of the second embodiment may be about 155 seconds less than that of the first embodiment. A cleaning time per substrate of the first embodiment may be about 60 seconds. A cleaning time per substrate of the second embodiment may be about 58 seconds. Accordingly, the cleaning time of the second embodiment may be about 2 seconds less than that of the first embodiment. As such, it is found that, in case that the flow control member 120 is used, a time taken to clean the inside of the chamber 110 may be reduced.

A monthly substrate production quantity of the first embodiment may be about 165,000. A monthly substrate production quantity of the second embodiment may be about 172,700. Accordingly, the monthly substrate production quantity of the second embodiment may be about 7,700 more than that of the first embodiment. Because a time taken to clean the inside of the chamber 110 may be shorter in the second embodiment than in the first embodiment, more display substrates may be produced by the amount of time, and thus, the monthly substrate production quantity of the second embodiment may be greater than that of the first embodiment.

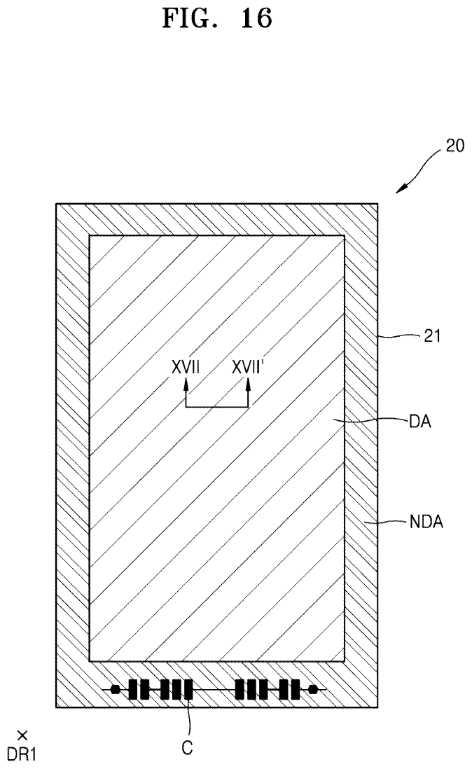

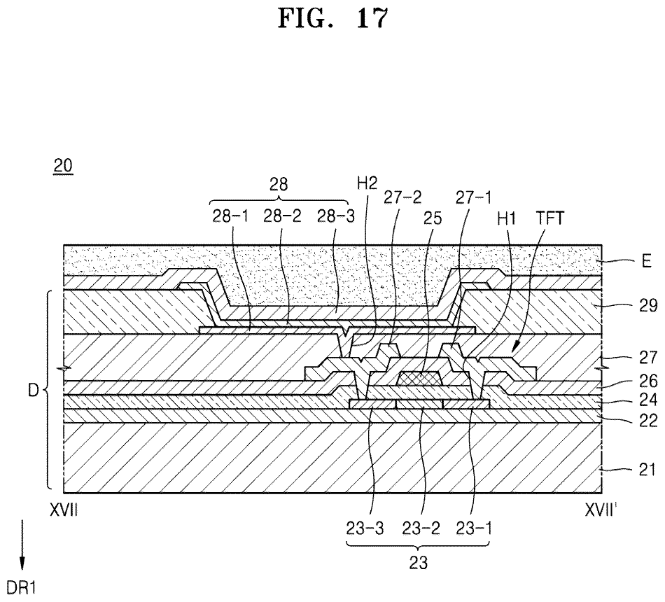

FIG. 16 is a schematic plan view illustrating a display apparatus manufactured by using a device for manufacturing a display apparatus according to an embodiment. FIG. 17 is a schematic cross-sectional view illustrating the display apparatus taken along line XVII-XVII′ of FIG. 12.

Referring to FIGS. 16 and 17, a display apparatus 20 may include a display area DA on a substrate 21 and a non-display area NDA outside the display area DA. In the display area DA, a light-emitting device 28 may be disposed, and in the non-display area NDA, a power supply wiring (not shown) may be disposed. Also, in the non-display area NDA, a pad part C may be disposed.

In the display area DA, multiple deposition material patterns may be disposed. The display area DA may have an irregular shape.

The display apparatus 20 may include the display substrate D, an intermediate layer 28-2 disposed on the display substrate D, and a counter electrode 28-3 disposed on the intermediate layer 28-2. Also, the display apparatus 20 may include a thin-film encapsulation layer E disposed on the counter electrode 28-3.

The display substrate D may include the substrate 21, a thin-film transistor TFT, a via layer 27, and a pixel electrode 28-1.

The substrate 21 may be formed of a plastic material or a metal material. Also, the substrate 21 may be formed of polyimide (PI). The thin-film transistor TFT may be disposed on the substrate 21, the via layer 27 may be disposed to cover the thin-film transistor TFT, and the light-emitting device 28 may be disposed on the via layer 27.

A buffer layer 22 formed of an organic compound and/or an inorganic compound may be further disposed on an upper surface of the substrate 21, and the buffer layer 22 may include SiOₓ (x≥1) and/or SiNₓ (x≥1).

After an active layer 23 arranged in a certain pattern may be disposed on the buffer layer 22, the active layer 23 may be covered by a gate insulating layer 24. The active layer 23 may include a source region 23-1 and a drain region 23-3, and may further include a channel region 23-2 between the source region 23-1 and the drain region 23-3. The active layer 23 may be formed to include various materials. In an embodiment, the active layer 23 may include an inorganic semiconductor material such as amorphous silicon or crystalline silicon. In an embodiment, the active layer 23 may include an oxide semiconductor. In an embodiment, the active layer 23 may include an organic semiconductor material. However, for convenience of explanation, the following will be described in detail assuming that the active layer 23 is formed of amorphous silicon.

The active layer 23 may be formed by forming an amorphous silicon film on the buffer layer 22, crystallizing the amorphous silicon film to form a polycrystalline silicon film, and patterning the polycrystalline silicon film. In the active layer 23, the source region 23-1 and the drain region 23-3 may be doped with impurities according to a TFT type such as a driving TFT (not shown) or a switching TFT (not shown).

A gate electrode 25 corresponding to the active layer 23 and an interlayer insulating layer 26 covering the gate electrode 25 may be disposed on an upper surface of the gate insulating layer 24. After a contact hole H1 may be formed in the interlayer insulating layer 26 and the gate insulating layer 24, a source electrode 27-1 and a drain electrode 27-2 may be disposed on the interlayer insulating layer 26 to respectively contact the source region 23-1 and the drain region 23-3.

The via layer 27 may be disposed on the thin-film transistor TFT, and the pixel electrode 28-1 of the light-emitting device 28 may be disposed on the via layer 27. The pixel electrode 28-1 contacts the drain electrode 27-2 of the thin-film transistor TFT through a via hole H2 formed in the via layer 27. The via layer 27 may include an inorganic material and/or an organic material and may have a single or multi-layer structure. The via layer 27 may be formed as a planarization film so that an upper surface thereof may be approximately flat regardless of a curvature of a lower film, or may be formed to be curved along a curvature of a lower film.

After the pixel electrode 28-1 is disposed on the via layer 27, a pixel-defining film 29 may be formed of an organic material and/or an inorganic material to cover the pixel electrode 28-1 and the via layer 27, and may be open to expose the pixel electrode 28-1.

The intermediate layer 28-2 and the counter electrode 28-3 may be disposed on the pixel electrode 28-1. In an embodiment, the counter electrode 28-3 may be disposed on an entire surface of the display substrate D. The counter electrode 28-3 may be disposed on the intermediate layer 28-2 and the pixel-defining film 29. For convenience of explanation, the following will be described in detail assuming that the counter electrode 28-3 is disposed on the intermediate layer 28-2 and the pixel-defining film 29.

The pixel electrode 28-1 may function as an anode and the counter electrode 28-3 may function as a cathode. However, polarities of the pixel electrode 28-1 and the counter electrode 28-3 may be switched. The pixel electrode 28-1 and the counter electrode 28-3 may be insulated from each other by the intermediate layer 28-2, and voltages of different polarities may be applied to the intermediate layer 28-2 to cause an organic emission layer to emit light.

The intermediate layer 28-2 may include the organic emission layer. In an optional example, the intermediate layer 28-2 may include the organic emission layer, and may further include at least one of a hole injection layer, a hole transport layer, an electron transport layer, and an electron injection layer. The embodiment is not limited thereto, and the intermediate layer 28-2 may include the organic emission layer and may further include various other functional layers (not shown).

A unit pixel may include multiple sub-pixels, and the sub-pixels may emit light of various colors. For example, the sub-pixels may include sub-pixels for emitting red light, green light, and blue light, or may include sub-pixels for emitting red light, green light, blue light, and white light. The sub-pixel may include an intermediate layer (e.g., single intermediate layer) 28-2.

The thin-film encapsulation layer E may include multiple inorganic layers or may include an inorganic layer and an organic layer. The organic layer of the thin-film encapsulation layer E may be formed of a polymer, and may have a single or multi-layer structure formed of any one of polyethylene terephthalate, polyimide, polycarbonate, epoxy, polyethylene, polyacrylate, or a combination thereof. The inorganic layer of the thin-film encapsulation layer E may have a single or multi-layer structure that may include a metal oxide or a metal nitride. In detail, the inorganic layer may include any one of SiNₓ, Al₂O₃, SiO₂, TiO₂, or a combination thereof. An uppermost layer exposed to the outside among layers of the thin-film encapsulation layer E may be an inorganic layer to prevent moisture penetration into the light-emitting device. The thin-film encapsulation layer E may be formed through the device for manufacturing a display apparatus described above.

The thin-film encapsulation layer E may include at least sandwich structure in which at least one organic layer may be inserted between at least two inorganic layers. In an example, the thin-film encapsulation layer E may include at least one sandwich structure in which at least one inorganic layer may be inserted between at least two organic layers. In an embodiment, the thin-film encapsulation layer E may include a sandwich structure in which at least one organic layer may be inserted between at least two inorganic layer and a sandwich structure in which at least one inorganic layer may be inserted between at least two organic layers.

According to an embodiment as described above, a flow direction of a cleaning material in a chamber 110 may be controlled. Accordingly, because a flow of the cleaning material may be guided to an area with a relatively low flow rate of the cleaning material in the chamber 110, gas does not need to be additionally injected to clean the area. Accordingly, the amount of cleaning material that should be injected to sufficiently clean the inside of the chamber 110 may be reduced.

Also according to an embodiment as described above, because a flow of a cleaning material may be controlled, a time taken to completely clean the inside of a chamber 110 with a certain amount of cleaning material may be reduced.

Also according to an embodiment as described above, because a flow control member capable of controlling a flow direction of a cleaning material may be readily attached to and detached from the inside of a chamber 110, maintenance of a device for manufacturing a display apparatus may be facilitated.

It should be understood that embodiments described herein should be considered in a descriptive sense only and not for purposes of limitation. Descriptions of features or aspects in each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A device for manufacturing a display apparatus, the device comprising:
a chamber having inner sides;
a susceptor disposed in the chamber;
a diffuser facing the susceptor;
a shadow frame disposed between the susceptor and the diffuser;
a fixing member disposed on at least one of the inner sides of the chamber; and
a flow control member disposed on the at least one of the inner sides of the chamber to correspond to the fixing member and comprising at least a part disposed under the susceptor,
wherein the flow control member is slidable in a direction upon being coupled to the fixing member.

2. The device of claim 1, wherein
one of the flow control member and the fixing member comprises a protrusion protruding in a direction, and
another of the flow control member and the fixing member comprises a receiving portion in which the protrusion is inserted.

3. The device of claim 2, wherein the flow control member is coupled to the fixing member by allowing the protrusion to slide into the receiving portion in a direction perpendicular to a protruding direction of the protrusion.

4. The device of claim 1, wherein the flow control member comprises:
a first portion contacting the at least one of the inner sides of the chamber; and
a second portion protruding in a direction substantially perpendicular to the at least one of the inner sides of the chamber.

5. The device of claim 4, wherein an end portion of the second portion is rounded.

6. The device of claim 4, wherein the second portion overlaps the shadow frame.

7. The device of claim 4, wherein
the flow control member further comprises a third portion disposed at an end portion of the second portion, and
an upper surface of the third portion is disposed at a higher position than an upper surface of the second portion.

8. The device of claim 1, wherein the at least one of the inner sides of the chamber comprises a groove in which at least a part of the fixing member is inserted.

9. The device of claim 8, wherein the fixing member comprises:
a first portion inserted in the groove and partially filling the groove; and
a second portion protruding to outside of the groove and coupled to the flow control member.

10. The device of claim 1, wherein in a first area adjacent to a corner of the chamber, a space over the flow control member and a space under the flow control member are in fluid communication.

11. A method of manufacturing a display apparatus, the method comprising:
providing a device for manufacturing the display apparatus that includes a chamber that includes inner sides;
depositing a deposition material on a substrate in the chamber and using a mask; and
cleaning an inside of the chamber with a cleaning material, wherein
the device for manufacturing a display apparatus comprises:
a fixing member disposed on at least one of the inner sides of the chamber; and
a flow control member disposed in the chamber, the flow control member sliding in a direction upon being coupled to the fixing member, and
a flow of the cleaning material is guided by the flow control member during the cleaning of the inside of the chamber.

12. The method of claim 11, wherein
one of the flow control member and the fixing member comprises a protrusion protruding in a direction, and
another of the flow control member and the fixing member comprises a receiving portion in which the protrusion is inserted.

13. The method of claim 12, wherein the flow control member is coupled to the fixing member by allowing the protrusion to slide into the receiving portion in a direction perpendicular to a protruding direction of the protrusion.

14. The method of claim 11, wherein the flow control member comprises:
a first portion contacting the at least one of the inner sides of the chamber; and
a second portion protruding in a direction substantially perpendicular to the at least one of the inner sides of the chamber.

15. The method of claim 14, wherein an end portion of the second portion is rounded.

16. The method of claim 14, wherein
the flow control member further comprises a third portion disposed at an end portion of the second portion, and
an upper surface of the third portion is disposed at a higher position than an upper surface of the second portion.

17. The method of claim 11, wherein the at least one of the inner sides of the chamber comprises a groove in which at least a part of the fixing member is inserted.

18. The method of claim 17, wherein the fixing member comprises:
a first portion inserted in the groove and partially filling the groove; and
a second portion protruding to outside of the groove and coupled to the flow control member.

19. The method of claim 11, wherein in the cleaning, a flow of the cleaning material is guided by the flow control member to at least one of corners inside the chamber.

20. The method of claim 11, wherein in the cleaning, a flow of the cleaning material between an upper side and a lower side inside the chamber is substantially performed in at least one of corners inside the chamber.
